(19) United States
(12) Patent Application Publication
(10) Pub. No.: US 2017/0053714 A1
(43) Pub. Date: Feb. 23, 2017

(54) READ VOLTAGE OFFSET

(71) Applicant: Micron Technology, Inc., Boise, ID (US)

(72) Inventors: Adam C. Guy, Boise, ID (US); Kishore K. Muchherla, San Jose, CA (US); Sampath K. Ratnam, Boise, ID (US)

(21) Appl. No.: 14/829,729

(22) Filed: Aug. 19, 2015

(51) Int. Cl. G11C 29/50; G11C 29/00; G06F 3/06; G11C 11/406; G06F 12/06

(52) U.S. Cl. CPC G11C 29/50004; G11C 11/40626; G06F 12/0638; G06F 3/0619; G06F 3/065; G06F 3/0653; G06F 3/0685; G11C 29/783; G06F 2212/205; G11C 2029/5004

(57) ABSTRACT

Apparatuses, methods, and data structures that can be utilized to provide a read voltage offset are described. One or more apparatuses can include a memory device and a controller coupled to the memory device and configured to: access a data structure comprising write temperature data corresponding to a number of data segments stored in the memory device; read a particular data segment using a read voltage offset determined based on: the write temperature data from the data structure and corresponding to the particular data segment; and read temperature data corresponding to the particular data segment.

### TECHNICAL FIELD

The present disclosure relates generally to semiconductor memory devices and methods and, more particularly, to apparatuses, methods, and data structures that can be utilized to provide a read voltage offset.

### BACKGROUND

Memory devices are typically provided as internal, semiconductor, integrated circuits in computers or other electronic devices. There are many different types of memory including volatile and non-volatile memory. Volatile memory can require power to maintain its data and includes random-access memory (RAM), dynamic random access memory (DRAM), and synchronous dynamic random access memory (SDRAM), among others. Non-volatile memory can provide persistent data by retaining stored information when not powered and can include NAND flash memory, NOR flash memory, read only memory (ROM), Electrically Erasable Programmable ROM (EEPROM), Erasable Programmable ROM (EPROM), and phase change random access memory (PCRAM), among others.

Memory devices can be combined together to form a solid state drive (SSD). A solid state drive can include non-volatile memory, e.g., NAND flash memory and NOR flash memory, and/or can include volatile memory, e.g., DRAM and SRAM, among various other types of non-volatile and volatile memory. Flash memory devices, including floating gate flash devices and charge trap flash (CTF) devices using semiconductor-oxide-nitride-oxide-semiconductor and metal-oxide-nitride-oxide-semiconductor capacitor structures that store information in charge traps in the nitride layer, may be utilized as non-volatile memory for a wide range of electronic applications. Flash memory devices typically use a one-transistor memory cell that allows for high memory densities, high reliability, and low power consumption.

An SSD can be used as a storage device. An SSD can have a number of advantages over hard drives in terms of performance, size, weight, ruggedness, operating temperature range, and power consumption, for example. For instance, SSDs can have improved performance for some applications when compared to magnetic disk drives due to the SSD's lack of moving parts, which may avoid seek time, latency, and other electro-mechanical delays associated with magnetic disk drives.

An SSD can include a number of memory devices, e.g., a number of memory chips. As used herein, “a number of” something can refer to one or more of such things, e.g., a number of memory devices can refer to one or more memory devices. As one of ordinary skill in the art will appreciate, a memory chip can include a number of dies and/or logical units (LUNs). Each die can include a number of memory arrays and peripheral circuitry thereon. The memory arrays can include a number of memory cells organized into a number of physical pages, and the physical pages can be organized into a number of blocks.

### BRIEF DESCRIPTION OF THE DRAWINGS

FIG. 1 is a functional block diagram of an apparatus in the form of a computing system including at least one memory system in accordance with one or more embodiments of the present disclosure.

FIG. 2 is a block diagram of a portion of data structure in accordance with one or more embodiments of the present disclosure.

### DETAILED DESCRIPTION

The present disclosure includes apparatuses, methods, and data structures that can be utilized to provide a read voltage offset. As an example, an apparatus can include a memory device and a controller coupled to the memory device and configured to access a data structure comprising write temperature data corresponding to a number of data segments stored in the memory device; read a particular data segment using a read voltage offset determined based on the write temperature data from the data structure and corresponding to the particular data segment, and read temperature data corresponding to the particular data segment.

Solid state drives (SSDs) for some applications, e.g., automotive, aeronautic, surveillance, among other applications, can have variable operating temperatures. These variable operating temperatures may include a wide range of temperatures. For example, the variable operating temperatures, e.g., of a memory device, may be from −40 degrees Celsius to 100 degrees Celsius, among other operating temperatures. NAND flash memory can be temperature sensitive. For example, in NAND flash memory, writing data at a first temperature and then reading the data at a second temperature, which is different than the first temperature, can result in an increased raw bit error rate (RBER), as compared to writing data and then reading the data at a same temperature. Previous approaches have utilized temperature compensation schemes, e.g., built in temperature compensation schemes. Built in temperature compensation schemes are utilized to adjust read voltages based upon an immediate temperature of the NAND. However, the voltage shifts that are experienced by the NAND flash memory may not correlate with an internal read voltage adjustment, particularly in an extreme cross-temperature condition, such as encountered in automotive applications, for instance. As such, under an extreme cross-temperature condition, the NAND flash memory may experience a voltage distribution shift relative to a read voltage position that results in an increased RBER.

An increase in RBER can result in correctable errors with an increased amount of failing bits and/or uncorrectable errors. Correctable errors with an increased amount of failing bits and/or uncorrectable errors can result in error handling and/or data refresh activity, both of which can lead to a performance reduction. Additionally, an increase in RBER can result in an increased write amplification, which can reduce an expected useful lifetime of the NAND flash memory. Embodiments of the present disclosure can provide benefits such as a reduced RBER, as compared to previous approaches.

In the following detailed description of the present disclosure, reference is made to the accompanying drawings that form a part hereof, and in which is shown by way of illustration how one or more embodiments of the disclosure may be practiced. These embodiments are described in sufficient detail to enable those of ordinary skill in the art to practice the embodiments of this disclosure, and it is to be understood that other embodiments may be utilized and that process, electrical, and/or structural changes may be made without departing from the scope of the present disclosure.

As used herein, the designators “N”, “M”, and “X” particularly with respect to reference numerals in the drawings, indicate that a number of the particular feature so designated can be included with one or more embodiments of the present disclosure. Additionally, as used herein, “a number of” something can refer to one or more such things. For example, a number of memory devices can refer to one or more memory devices.

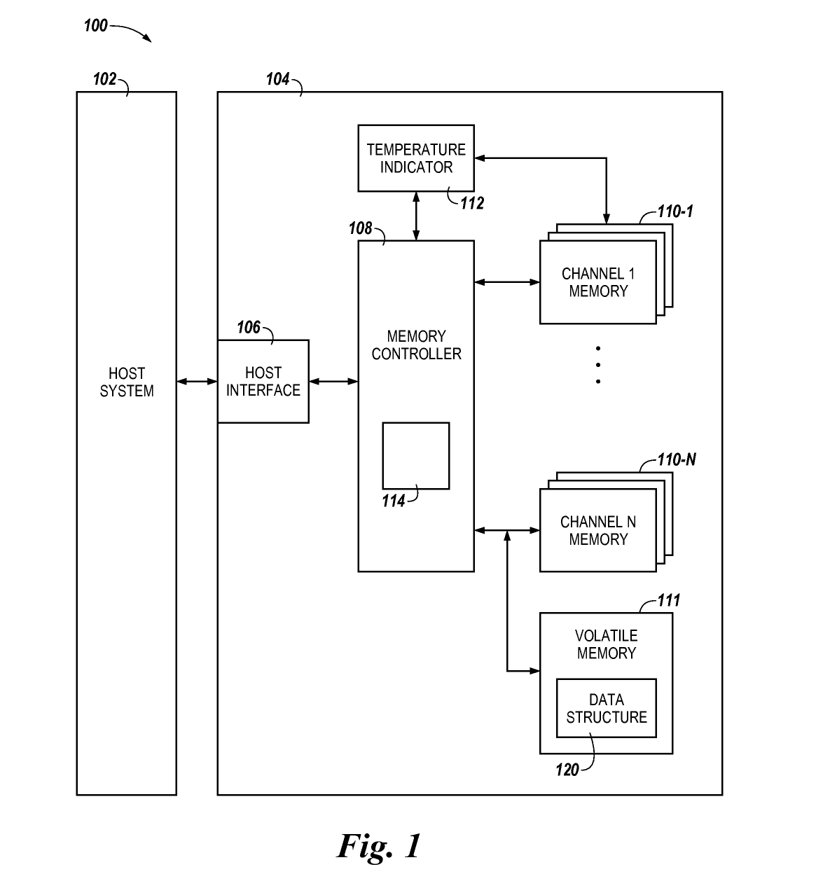

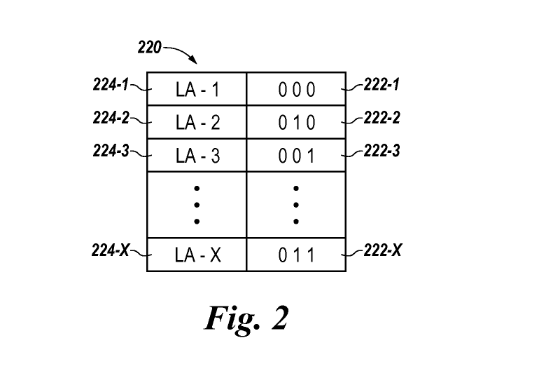

The figures herein follow a numbering convention in which the first digit corresponds to the drawing figure number and the remaining digits identify an element or component in the drawing. Similar elements or components between different figures may be identified by the use of similar digits. For example, 120 may reference element “20” in FIG. 1, and a similar element may be referenced as 220 in FIG. 2. As will be appreciated, elements shown in the various embodiments herein can be added, exchanged, and/or eliminated so as to provide a number of additional embodiments of the present disclosure. In addition, as will be appreciated, the proportion and/or the relative scale of the elements provided in the figures are intended to illustrate the embodiments of the present invention and should not be taken in a limiting sense.

FIG. 1 is a block diagram of an apparatus in the form of a computing system 100 including at least one memory system 104 in accordance with a number of embodiments of the present disclosure. As used herein, a memory system 104, a controller 108, memory devices 110-1, . . . , 110-N and 111, or a temperature indicator 112 may also be separately considered an “apparatus.” The memory system 104 can include a host interface 106, a controller 108, e.g., a processor and/or other control circuitry, a number of memory devices 110-1, . . . , 110-N, e.g., solid state memory devices such as charge-trapping NAND flash devices, and memory device 111, e.g., DRAM. The memory devices 110, 111 can provide a storage volume for the memory system 104. The memory system 104 can be a single memory device.

As illustrated in FIG. 1, the controller 108 can be coupled to the host interface 106 and to the memory devices 110-1, . . . , 110-N, 111 via a plurality of channels and can be used to send data between the memory system 104 and a host 102. The interface 106 can be in the form of a standardized interface. For example, when the memory system 104 is used for data storage in a computing system 100, the interface 106 can be a serial advanced technology attachment (SATA), peripheral component interconnect express (PCIe), or a universal serial bus (USB), among other connectors and interfaces. In general, however, interface 106 can provide an interface for passing control, address, data, and other signals between the memory system 104 and a host 102 having compatible receptors for the interface 106.

Host 102 can be different a variety of different host systems for different applications. For example, host 102 can be a host system such as a personal laptop computer, a desktop computer, a digital camera, a mobile telephone, or a memory card reader, among various other types of hosts. Host 102 can include a system motherboard and/or backplane and can include a number of memory access devices, e.g., a number of processors. Host 102 can also be a memory controller, such as where memory system 104 is a memory device, e.g., having an on-die controller.

The controller 108 can communicate with the memory devices 110-1, . . . , 110-N, 111 to control data read, write, and erase operations, among other operations. The memory controller 108 can include non-volatile memory control circuitry and volatile memory control circuitry. The memory controller 108 can communicate with the memory devices 110-1, . . . , 110-N, 111 to read, write, and erase information, among other operations. Although the memory devices 110-1, . . . , 110-N are illustrated being coupled to a collective memory controller 108, a number of embodiments of the present disclosure can include a discrete memory controller for each memory channel. Additionally, although the memory device 111 is illustrated being coupled to the collective memory controller 108 by a particular channel, embodiments of the present disclosure are not so limited. The memory device 111 may be coupled to the collective memory controller 108 by a number of channels.

A memory device 110-1, . . . , 110-N can include a number of arrays of memory cells, e.g., non-volatile memory cells. The arrays can be flash arrays with a NAND architecture, for example. In a NAND architecture, the control gates of memory cells of a “row” can be coupled with an access, e.g., word, line, while the memory cells can be coupled in series source to drain in a “string” between a select gate source transistor and a select gate drain transistor. The string can be connected to a data line, e.g., bit line, by the select gate drain transistor. The use of the terms “row” and “string” implies neither a linear nor an orthogonal arrangement of memory cells. As will be appreciated by those of ordinary skill in the art, the manner of connection of the memory cells to the bit lines and source lines depends on whether the array is a NAND architecture, a NOR architecture, or some other memory array architecture.

The memory devices 110-1, . . . , 110-N can include a number of memory cells that can be grouped. As used herein, a group can include a number of memory cells, such as a page, block, plane, die, an entire array, or other groups of memory cells. For example, some memory arrays can include a number of pages of memory cells that make up a block of memory cells. A number of blocks can be included in a plane of memory cells. A number of planes of memory cells can be included on a die. As an example, a 128 GB memory device can include 4314 bytes of information per page, e.g., 4096 bytes of write information plus 218 bytes of overhead information, 128 pages per block, 2048 blocks per plane, and 16 planes per device.

A memory device 111 can include a number of arrays of memory cells, e.g., volatile memory cells. The array can include volatile memory cells arranged in rows coupled by access lines, which may be referred to herein as word lines or select lines, and columns coupled by sense lines, which may be referred to herein as digit lines or data lines. The array including volatile memory cells can be coupled to sensing circuitry in accordance with a number of embodiments of the present disclosure. Embodiments of the present disclosure provide that the memory device 111 may be random access memory (RAM), dynamic random access memory (DRAM), static random access memory (SRAM), synchronous dynamic random access memory (SDRAM), or thyristor random access memory (TRAM), among others. As illustrated in FIG. 1, a data structure 120 can be stored on the memory device 111. However, embodiments are not limited. For example, the data structure 120 can be stored on a memory device 110 and/or in memory on the controller 108, for instance. A number of embodiments of the present disclosure provide that the data structure 120 can be a flash transition layer structure.

As discussed further herein, the data structure 120 can be utilized to store write temperature data that corresponds to a range of temperatures including the write temperature of particular data segments. A read voltage offset can be used when reading a number of the particular data segments. For example, a read voltage offset can be determined based on the write temperature data, e.g., in data structure 120, and read temperature data. Utilizing the read voltage offset can help to provide a reduced RBER, as compared to previous approaches.

Although not specifically illustrated in FIG. 1, in some embodiments, the controller 108 can include a discrete memory channel controller for each channel coupling the controller 108 to the memory devices 110-1, . . . , 110-N and/or memory device 111. The controller 108 can include, for example, a number of components in the form of hardware and/or firmware, e.g., a number of integrated circuits, and/or software for controlling access to the memory devices 110-1, . . . , 110-N, 111 and/or for facilitating data transfer between the host 102 and memory devices 110-1, . . . , 110-N, 111.

In operation, data can be written to and/or read from memory, e.g., memory devices 110-1, . . . , 110-N of system 104, as a page of data, for example. As such, a page of data can be referred to as a data transfer size of the memory system. Data can be sent to/from a host (e.g., host 102) in data segments referred to as sectors, e.g., host sectors. As such, a sector of data can be referred to as a data transfer size of the host.

The controller 108 can include logical-to-physical translation circuitry 114, among other circuitry. The circuitry, e.g., the logical-to-physical translation circuitry 114 can include discrete components, such as an application specific integrated circuit (ASIC), or the components may reflect functionality provided by circuitry and/or executable instructions within the controller 108 that does not necessarily have a discrete physical form separate from other portions of the controller 108. For example, the logical-to-physical translation circuitry 114 can be external to the controller 108 or have a number of components located within the controller 108 and a number of components located external to the controller 108. Functionality described herein, e.g., by the logical-to-physical translation circuitry 114, can be provided as a non-transitory electronic device readable medium storing instructions executable by the electronic device, e.g., firmware in the controller 108, to provide the functionality, for example.

The logical-to-physical translation circuitry 114 can be used to convert between host and/or file system addresses and memory addresses, for instance. In some embodiments, the logical-to-physical translation circuitry 114 can include a flash translation layer. The logical-to-physical translation circuitry 114 can be used, e.g., during a programming operation performed on the memory devices 110-1, . . . , 110-N, to map a logical address associated with a data entry to a physical address in the memory devices 110-1, . . . , 110-N. The logical-to-physical translation circuitry 114 may include an address mapping table in the local memory of the controller 108 to perform the mapping operation, for example. A host 102 can use logical block addresses (LBAs) when addressing a memory system 104. The logical-to-physical translation circuitry 114 can translate an LBA to a physical location in the memory devices 110-1, . . . , 110-N, and vice versa.

The system 100 can include a temperature indicator 112. The temperature indicator 112 may be utilized to determine a temperature of a memory devices 110-1, . . . , 110-N at a particular time. For example, the temperature indicator 112 can determine a write temperature of a memory device, e.g., memory device 110-1, when a memory cell of the memory device is programmed, e.g., written. The temperature indicator 112 can determine a read temperature of a memory device, e.g., memory device 110-1, when a memory cell of the memory device is read. A number of embodiments of the present disclosure provide that determined write temperatures can be communicated to the controller 108 and/or a memory device, e.g., memory device 111. For instance, the controller 108 can access the temperature indicator 112.

FIG. 2 is a block diagram of a portion of data structure 220 in accordance with one or more embodiments of the present disclosure. As shown in FIG. 2, the data structure 220 can include write temperature data 222-1, 222-2, 222-3, . . . , 222-X. The write temperature data 222-1, 222-2, 222-3, . . . , 222-X respectively correspond to a temperature of a non-volatile memory device, e.g., a memory device 110 discussed with FIG. 1, at which particular data segments having respective logical addresses LA-1, LA-2, LA-3, . . . , LA-X corresponding to 224-1, 224-2, 224-3, . . . , 224-X were written to the non-volatile memory device. For example, a particular data segment can be written to a non-volatile memory device and have a corresponding logical address 224-1; write temperature data 222-1 indicates a write temperate that the non-volatile memory device had when the particular data segment was written.

Write temperature data 222-1, 222-2, 222-3, . . . , 222-X can respectively include a number of bits. For instance, as shown in FIG. 2, write temperature data 222-1 includes three bits, i.e. “000.” However, embodiments of the present disclosure are not so limited. For example, a number of embodiments of the present disclosure can provide that a particular write temperature data can include less than or greater than three bits. For instance, a number of embodiments of the present disclosure provide that a particular write temperature data can include a number of bits, such as from two to eight bits, among other numbers of bits. A number of embodiments provide that utilizing the numbers of bits for particular write temperature data can help to reduce an amount of data stored in the data structure 220, e.g., an amount of data attributable to write temperature data, as compared to some logical-to-physical tables managed by SSD firmware, for instance. Additionally, a number of embodiments of the present disclosure provide that size of data structure 220 can be reduced due to parallelism implemented in SSD firmware. For example, a memory device where eight logic units (LUN) are programmed simultaneously may have 32 KB of data written to each LUN in a dual-plane program sequence. For this example, the firmware may utilize a single write temperature data for each 256 KB of user data stored to the memory device. The data structure 220 can help to reduce an overhead and/or maintenance impact, e.g., when portions of the data structure 220 are periodically transferred from volatile memory to non-volatile memory. The periodic transfer of portions of the data structure 220 from volatile memory to non-volatile memory can help to provide that write temperature data is not lost in the event of an unexpected power loss, for instance.

A particular write temperature may correspond to a range of temperatures. For example, write temperature data 222-1, which is shown in FIG. 2 as “000” may correspond to a range of temperatures from −40 degrees Celsius to −20 degrees Celsius. In other words for this example, if a non-volatile memory device has a temperature from −40 degrees Celsius to −20 degrees Celsius when a particular data segment, e.g. a data segment corresponding to LA-1, is written to the non-volatile memory device then the corresponding write temperature data will be “000”. Similarly, if the non-volatile memory device has the temperature from −40 degrees Celsius to −20 degrees Celsius when other particular data segments are written to the non-volatile memory device, those other particular data segments will respectively also have “000” write temperature data.

A number of embodiments provide that ranges of temperatures can have different intervals. For example, the range of temperatures from −40 degrees Celsius to −20 degrees Celsius, as discussed above, has an interval of 20 degrees Celsius.

For some applications, a relatively lesser precision may be acceptable and/or desired and a relatively larger interval, e.g. an interval of twenty-five, thirty, or thirty-five degrees Celsius may be utilized, for example. A number of embodiments provide that when ranges of temperatures utilize relatively larger intervals, the respective write temperature data can utilize fewer bits, as compared to write temperature data associated with ranges of temperatures utilizing smaller intervals. For example, the range of temperatures from −40 degrees Celsius to −20 degrees Celsius, as discussed above, has an interval of twenty degrees Celsius and corresponding write temperature data of “000”; with a relatively larger interval, e.g. an interval of thirty degrees Celsius, the corresponding write temperature data may utilize fewer bits, e.g., “00.”

For some applications, a relatively greater precision may be acceptable and/or desired and a relatively smaller interval, e.g. an interval of one, five, ten, or fifteen degrees Celsius may be utilized, for example. A number of embodiments provide that when ranges of temperatures utilize relatively smaller intervals, the respective write temperature data can utilize more bits, as compared to write temperature data associated with ranges of temperatures utilizing larger intervals. For example, the range of temperatures from −40 degrees Celsius to −20 degrees Celsius, as discussed above, has an interval of twenty degrees Celsius and corresponding write temperature data of “000”. When a relatively smaller interval, e.g. an interval of ten degrees Celsius, the corresponding write temperature data may utilize more bits, e.g., “0000.”

A number of embodiments provide that the data structure 220 can include a plurality of write temperature data that respectively correspond to a plurality of ranges of temperatures. In other words, the data structure 220 can include a plurality of write temperature data that respectively correspond to a plurality of respectively stored particular data segments. As an example, some applications are associated with operating temperatures from −40 degrees Celsius to 80 degrees Celsius. Utilizing an interval of twenty degrees Celsius, the data structure 220 can include first write temperature data that corresponds to a write temperature that is from −40 degrees Celsius to −20 degrees Celsius, a second write temperature data that corresponds to a write temperature that is from greater than −20 degrees Celsius to 0 degrees Celsius, and a third write temperature data that corresponds to a write temperature that is from greater than 0 degrees Celsius to 20 degrees Celsius, and so forth.

Read operation can performed to read data segments stored in a memory device by utilizing a read voltage. As mentioned, for NAND flash memory, writing data at a first temperature and then reading the data at a second temperature, which is different than the first temperature, can result in a high RBER. Previous approaches have utilized temperature compensation schemes, e.g., built in temperature compensation schemes.

Referring back to FIG. 1, a number of embodiments provide that the data structure 120 can be stored in volatile memory, e.g., memory device 111. For a read operation, e.g., reading a number of data segments stored in memory device 110, the controller 108 can access the data structure to determine write temperature data corresponding to a number the data segments being read. The controller 108 can access the temperature indicator 112 to determine read temperature data, e.g., a temperature of the memory device 110 at a time corresponding to the read operation. For a particular data segment being read, a read voltage offset may be utilized, where the read voltage offset is based upon the write temperature data corresponding to the particular data segment and the read temperature data. In other words, the read voltage offset can be utilized to account for a temperature difference of a memory device 110 at a time of writing a data segment to the memory device 110 and a time of reading the data segment from the memory device 110. Advantageously, utilizing the read voltage offset can help to provide a reduced RBER, as compared to previous approaches.

For some instances, e.g., associated with particular write temperature data, a read voltage offset may be utilized to increase a read voltage. Additionally, various read voltage offsets may be utilized to increase the read voltage by different amounts. For example, a first read voltage offset that is based upon first write temperature data corresponding to a first particular data segment and read temperature data may increase a read voltage by a first amount and a second read voltage offset that is based upon second write temperature data corresponding to a second particular data segment and the read temperature data may increase a read voltage by a second amount, where the first amount is different than the second amount.

For some other instances, e.g. associated with particular write temperature data, a read voltage offset may be utilized to decrease a read voltage. Additionally, various read voltage offsets may be utilized to decrease the read voltage by different amounts. For example, a first read voltage offset that is based upon first write temperature data corresponding to a first particular data segment and read temperature data may decrease a read voltage by a first amount and a second read voltage offset that is based upon second write temperature data corresponding to a second particular data segment and the read temperature data may decrease a read voltage by a second amount, where the second amount is different than the second amount.

A number of embodiments of the present disclosure provide that write temperature data may be programmed as metadata. For example, write temperature data may be programmed to an auxiliary area, also referred to as a spare area of a page. As mentioned, a periodic transfer of portions of the data structure from volatile memory to non-volatile memory can help to provide that write temperature data is not lost in the event of an unexpected power loss. However, in the event of an unexpected power loss prior to a portion of the data structure transferred from volatile memory to non-volatile memory, the data structure may be reconstructed from write temperature data programmed as metadata.

Although specific embodiments have been illustrated and described herein, those of ordinary skill in the art will appreciate that an arrangement calculated to achieve the same results can be substituted for the specific embodiments shown. This disclosure is intended to cover adaptations or variations of one or more embodiments of the present disclosure. It is to be understood that the above description has been made in an illustrative fashion, and not a restrictive one. Combination of the above embodiments, and other embodiments not specifically described herein will be apparent to those of skill in the art upon reviewing the above description. The scope of the one or more embodiments of the present disclosure includes other applications in which the above structures and methods are used. Therefore, the scope of one or more embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. An apparatus, comprising:
a memory device; and
a controller coupled to the memory device and configured to:
access a data structure comprising write temperature data corresponding to a number of data segments stored in the memory device;
read a particular data segment using a read voltage offset determined based on:
the write temperature data from the data structure and corresponding to the particular data segment; and
read temperature data corresponding to the particular data segment.

2. The apparatus of claim 1, wherein a memory device storing the data structure is volatile memory.

3. The apparatus of claim 1, wherein the memory device storing the data structure is non-volatile memory.

4. The apparatus of claim 3, wherein the non-volatile memory includes the write temperature data programmed as metadata.

5. The apparatus of claim 1, wherein the write temperature data corresponds to a range of temperatures.

6. The apparatus of claim 1, wherein the data structure is configured to include additional write temperature data respectively corresponding to additional data segments.

7. The apparatus of claim 1, wherein the write temperature data comprises from two to eight bits.

8. The apparatus of claim 1, wherein the controller is further configured to access a temperature indicator.

9. A method for providing a read voltage offset, comprising:
programming, at a write temperature, a first memory cell;
storing, in a data structure, write temperature data corresponding to a range of temperatures including the write temperature;
reading the memory cell using a first read voltage offset, wherein the read voltage offset is determined based on the write temperature data and read temperature data.

10. The method of claim 9, further comprising storing, in the data structure, subsequent write temperature data corresponding to a subsequent range of temperatures including a subsequent write temperature.

11. The method of claim 10, further comprising reading a second memory cell using a second read voltage offset, wherein the second read voltage offset is determined based on the second write temperature data and subsequent read temperature data.

12. The method of claim 11, wherein the first read voltage offset is greater than the second read voltage offset.

13. The method of claim 11, wherein the first read voltage offset is less than the second read voltage offset.

14. The method of claim 9, wherein determining the first read voltage offset includes determining a difference between the range of temperatures including the write temperature and a read temperature.

15. The method of claim 9, further comprising accessing the data structure in a volatile memory device. and storing the accessed data structure in a non-volatile memory device.

16. The method of claim 15, further comprising storing the accessed data structure in a non-volatile memory device.

17. A data structure stored in a memory device, comprising:
write temperature data that indicates a ranges of temperatures at which each of a number of stored data segments were written to memory.

18. The data structure of claim 17, wherein each of the plurality of write temperature data includes a number of bits.

19. The data structure of claim 17, wherein a first portion of the write temperature data comprises a first range of temperatures is an interval from one degree Celsius to thirty-five degrees Celsius.

20. The data structure of claim 19, wherein a second portion of the write temperature data comprises a second range of temperatures.

21. The data structure of claim 20, wherein the first range of temperatures is different than the second range of temperatures.

22. The data structure of claim 17, wherein the data structure is configured to be accessed by a controller that is configured to read a particular data segment using a read voltage offset determined based on write temperature data corresponding to the particular data segment and read temperature data.

23. An apparatus, comprising:
a non-volatile memory device configured to store a number of data segments;
a volatile memory device configured to store a data structure, wherein the data structure is configured to store write temperature data corresponding to the number of data segments stored in the non-volatile memory device; and
a controller coupled to the non-volatile memory device and the volatile memory device, the controller configured to:
access the data structure to retrieve write temperature data corresponding to a particular data segment of the number of data segments stored in the memory device; and
read the particular data segment using a read voltage offset determined based on a difference between the write temperature data corresponding to the particular data segment and read temperature data corresponding to the particular data segment.

24. The apparatus of claim 23, wherein the non-volatile memory has a write temperature from −40 degrees Celsius to 100 degrees Celsius.
